(19) United States
(12) Patent Application Publication
(10) Pub. No.: US 2009/0021979 A1
(43) Pub. Date: Jan. 22, 2009

(54) Gate stack, capacitorless dynamic random access memory including the gate stack and methods of manufacturing and operating the same

(75) Inventors: Jung-hun Sung, Yongin-si (KR); Kwang-soo Seol, Suwon-si (KR); Woong-chul Shin, Daejeon (KR); Sang-jin Park, Yongin-si (KR); Sang-moo Choi, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 12/007,012

(22) Filed: Jan. 4, 2008

(30) Foreign Application Priority Data
Jul. 18, 2007 (KR) 10-2007-0071701

(51) Int. Cl. G11C 11/40; H01L 27/108; H01L 21/8242

(52) U.S. Cl. 365/184; 257/324; 438/591; 438/287; 257/E27.086; 257/E21.625

(57) ABSTRACT

Provided are a gate stack, a capacitorless dynamic random access memory (DRAM) including the gate stack and methods of manufacturing and operating the same. The gate stack for a capacitorless DRAM may include a tunnel insulating layer on a substrate, a first charge trapping layer on the tunnel insulating layer, an interlayer insulating layer on the first charge trapping layer, a second charge trapping layer on the interlayer insulating layer, a blocking insulating layer on the second charge trapping layer, and a gate electrode on the blocking insulating layer. The capacitorless DRAM may include the gate stack on the substrate, and a source and a drain in the substrate on both sides of the gate stack.

### PRIORITY STATEMENT

This application claims priority under 35 U.S.C. §119 to Korean Patent Application No. 10-2007-0071701, filed on Jul. 18, 2007, in the Korean Intellectual Property Office (KIPO), the entire contents of which are incorporated herein by reference.

### BACKGROUND

1. Field

Example embodiments relate to a gate stack, a semiconductor device including the gate stack and methods of manufacturing and operating the same. Other example embodiments relate to a gate stack, a charge trapping capacitorless dynamic random access memory (DRAM) including the gate stack and methods of manufacturing and operating the same.

2. Description of the Related Art

A conventional charge trapping memory device may have a gate stack in which a tunnel insulating layer, a charge trapping layer (a layer in which charges are trapped), a blocking insulating layer, and a gate electrode are sequentially stacked. The gate stack may be formed on a substrate, and a source and a drain may be respectively formed in both sides of the substrate. The gate stack, the source, and the drain form a transistor. Binary data may be written by trapping charges in the charge trapping layer or discharging the charges trapped in the charge trapping layer.

The conventional charge trapping memory device has the following problems. Data writing and erasing operations require may repetitive turn-on and turn-off operations of the transistor. Accordingly, the conventional charge trapping memory device may consumes a relatively large amount of power. Also, when data writing, erasing, and refreshing operations are performed, charges may be repeatedly moved through the tunnel insulating layer. Therefore, the characteristics of the tunnel insulating layer may deteriorate more easily. In addition, when a data reading operation is performed, a distribution state of the charges in the charge trapping layer may be more easily changed by a reading voltage. Accordingly, a read disturbance in the tunnel insulating layer may occur.

### SUMMARY

Example embodiments provide a gate stack and a charge trapping capacitorless dynamic random access memory (DRAM) that consume less power, and may prevent or reduce deterioration of characteristics of a tunnel insulating layer and read disturbance. Example embodiments also provide a method of manufacturing the gate stack and methods of manufacturing and operating the charge trapping capacitorless DRAM.

According to example embodiments, a gate stack for a capacitorless DRAM may include a tunnel insulating layer on a substrate, a first charge trapping layer on the tunnel insulating layer, an interlayer insulating layer on the first charge trapping layer, a second charge trapping layer on the interlayer insulating layer, a blocking insulating layer on the second charge trapping layer, and a gate electrode on the blocking insulating layer.

According to example embodiments, a method for manufacturing a gate stack for a capacitorless DRAM may include forming a tunnel insulating layer on a substrate, forming a first charge trapping layer on the tunnel insulating layer, forming an interlayer insulating layer on the first charge trapping layer, forming a second charge trapping layer on the interlayer insulating layer, forming a blocking insulating layer on the second charge trapping layer, and forming a gate electrode on the blocking insulating layer.

A thickness of the tunnel insulating layer may be in the range of about 4 nm to about 10 nm. The first and second charge trapping layers may be one of a high dielectric layer having a dielectric constant greater than that of a silicon nitride layer, a dielectric layer doped with metals, a dielectric layer in which nano-particles are embedded, an amorphous silicon nitride layer, a crystalline silicon nitride layer, and an amorphous silicon layer. A thickness of the first charge trapping layer may be in the range of about 4 nm to about 15 nm. A thickness of the second charge trapping layer may be in the range of about 4 nm to about 15 nm. The interlayer insulating layer may be a silicon oxide layer. A thickness of the interlayer insulating layer may be in the range of about 0.5 nm to about 3 nm.

According to example embodiments, a capacitorless DRAM may include the gate stack according to example embodiments on the substrate, and a source and a drain in the substrate on both sides of the gate stack. According to example embodiments, a method of manufacturing a capacitorless DRAM may include forming the gate stack according to example embodiments on the substrate, and forming a source and a drain in the substrate on both sides of the gate stack.

According to example embodiments, a method of operating a capacitorless DRAM including a gate stack in which a tunnel insulating layer, a first charge trapping layer, an interlayer insulating layer, a second charge trapping layer, a blocking insulating layer and a gate electrode are sequentially formed on a substrate, and a source and a drain respectively formed in the substrate on both sides of the gate stack may include applying a voltage to the gate stack.

The voltage may be a writing voltage, a reading voltage, an erasing voltage and/or a refreshing voltage. The writing voltage may be a voltage for trapping charges in the first and second charge trapping layers. The writing voltage may be applied to at least one of the source, the drain, the substrate, and the gate electrode in order to trap charges in the first and second charge trapping layers. The writing voltage may be a first writing voltage. After applying the first writing voltage, a second writing voltage different from the first writing voltage may be applied to the gate electrode.

The second writing voltage may be a voltage used for moving at least a part of the charges trapped in the first charge trapping layer to the second charge trapping layer. All charges in the first charge trapping layer may be moved to the second charge trapping layer by the second writing voltage. After applying the second writing voltage, a voltage for moving at least a part of the charges trapped in the second charge trapping layer to the first charge trapping layer may be applied to the gate electrode.

### BRIEF DESCRIPTION OF THE DRAWINGS

Example embodiments will be more clearly understood from the following detailed description taken in conjunction with the accompanying drawings. FIGS. 1-3 represent non-limiting, example embodiments as described herein.

FIG. 1 is a cross-sectional view illustrating a capacitorless dynamic random access memory (DRAM) according to example embodiments;

FIGS. 2A-2C are cross-sectional views for explaining a method of operating the capacitorless DRAM of FIG. 1, according to example embodiments; and

FIG. 3 is a graph illustrating sequential changes in a drain current in the method of operating the capacitorless DRAM of FIG. 1, according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

A capacitorless dynamic random access memory (DRAM) according to example embodiments and a method of operating the same will now be described more fully with reference to the accompanying drawings in which example embodiments are shown. In the drawings, the thicknesses of layers and regions are exaggerated for clarity, and like reference numerals refer to like elements.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

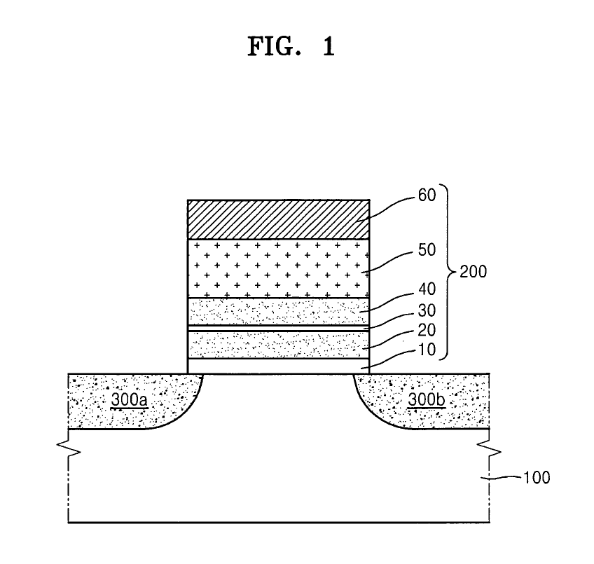

FIG. 1 is a cross-sectional view illustrating a capacitorless DRAM according to example embodiments. Referring to FIG. 1, a gate stack 200 may be formed on a substrate 100. A source 300a and a drain 300b may be respectively formed in the substrate 100 on both sides of the gate stack 200. The gate stack 200 may have a structure in which a tunnel insulating layer 10, a first charge trapping layer 20, an interlayer insulating layer 30, a second charge trapping layer 40, a blocking insulating layer 50, and a gate electrode 60 are sequentially stacked. The gate stack 200, the source 300a and the drain 300b form a transistor. The gate stack 200 may provide a space where data is stored. Because the capacitorless DRAM according to example embodiments has a 1T (transistor) structure in which one transistor is included in one memory cell, the capacitorless DRAM may be made smaller and more highly integrated, compared to a conventional DRAM, for example, a DRAM having a 1T (transistor)-1C (capacitor) structure in which a transistor and a capacitor are included in one memory cell.

The tunnel insulating layer 10 may be a silicon oxide layer, or a different material layer under different conditions. The thickness of the tunnel insulating layer 10 may be in the range of about 4 nm to about 10 nm. First and second charge trapping layers 20 and 40 may be silicon nitride layers. The silicon nitride layer may be amorphous or crystalline. The material of the first and second charge trapping layers 20 and 40 may be different. For example, the first and second charge trapping layers 20 and 40 may be one of a high dielectric layer having a dielectric constant greater than that of a silicon nitride layer, a dielectric layer doped with metals, a dielectric layer in which nano-particles are embedded, and an amorphous silicon layer.

Thicknesses of the first and second charge trapping layers 20 and 40 may be in the range of about 4 nm to about 5 nm, e.g., about 7 nm. The interlayer insulating layer 30 interposed between the first charge trapping layer 20 and the second charge trapping layer 40 may be a silicon oxide layer. The thickness of the interlayer insulating layer 30 may be in the range of about 0.5 nm to about 3 nm, for example, about 1 nm to about 2 nm. The blocking insulating layer 50 may be a high dielectric layer, e.g., an aluminum oxide layer and/or a Ln-based oxide layer. The aluminum oxide layer may be an α-alumina layer and/or a γ-alumina layer. The thickness of the blocking insulating layer 50 may be greater than about 20 nm. The gate electrode 60 may be formed of a metal and/or a conductive semiconductor.

In the capacitorless DRAM having the structure shown in FIG. 1, charges may be trapped in the first and second charge trapping layers 20 and 40. The charges trapped in the first charge trapping layer 20 may move to the second charge trapping layer 40 or the charges trapped in the second charge trapping layer 40 may move to the first charge trapping layer 20. Binary data may be written and erased by controlling the trapping state of the charges in the first and second charge trapping layers 20 and 40.

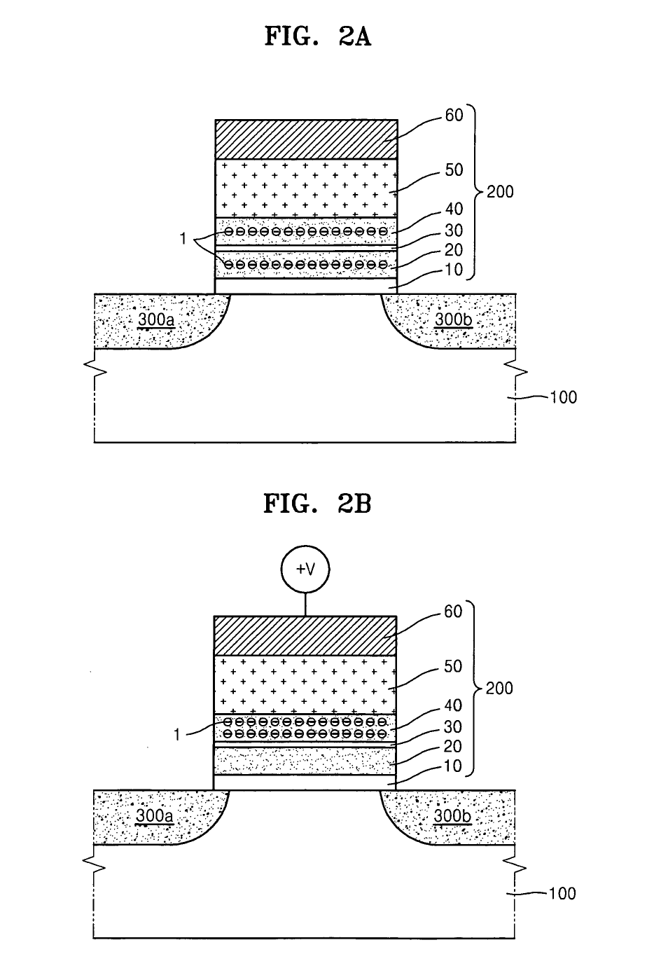

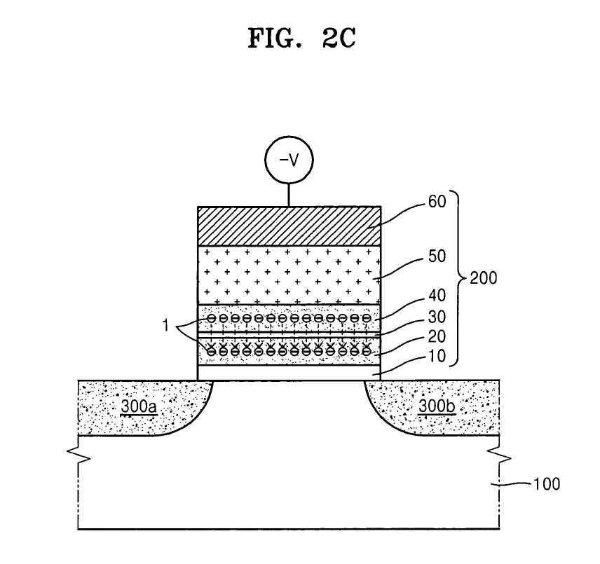

FIGS. 2A-2C are cross-sectional views for explaining a method of operating the capacitorless DRAM of FIG. 1, according to example embodiments. In FIG. 1 and FIGS. 2A through 2C, like reference numerals refer to like elements. Referring to FIG. 2A, charges, for example, electrons 1, may be injected into the first and second charge trapping layers 20 and 40. A method for injecting the electrons 1 into the first and second charge trapping layers 20 and 40 may be a novel hot electron injection (NHEI) method, a channel hot electron injection (CHEI) method, a fowler-nordheim tunneling method and/or a modified fowler-nordheim tunneling method. To inject the electrons 1 into the first and second charge trapping layers 20 and 40 using one of the above methods, a predetermined or given voltage may be applied to at least one of the source 300a, the drain 300b, the substrate 100, and the gate electrode 60.

For example, if a positive voltage and a negative voltage are respectively applied to the gate electrode 60 and the drain 300b, the electrons 1 may be injected into the first and second charge trapping layers 20 and 40 using the NHEI method. If a positive voltage and a ground voltage are respectively applied to the gate electrode 60 and the substrate 100, the electrons 1 may be injected into the first and second charge trapping layers 20 and 40 using the fowler-nordheim tunneling method. The blocking insulating layer 50 may serve to prevent or reduce the electrons 1 from being ejected to the gate electrode 60 during injecting the electrons 1. An operation shown in FIG. 2A may be a writing operation for first data, or a preliminary operation for writing second data. The electrons 1 may be injected into the first and second charge trapping layers 20 and 40 through the tunnel insulating layer 10.

Referring to FIG. 2B, at least part of the electrons 1 trapped in the first charge trapping layer 20 may be moved to the second charge trapping layer 40. All of the electrons 1 trapped in the first charge trapping layer 20 may be moved to the second charge trapping layer 40. A predetermined or given positive voltage (+V) may be applied to the gate electrode 60. The electrons 1 trapped in the first charge trapping layer 20 may be moved to the second charge trapping layer 40, thereby reducing a threshold voltage. The threshold voltage may be a threshold voltage of the transistor including the gate stack 200, the source 300a, and the drain 300b. Reduction of the threshold voltage may represent an increase in a drain current (Id).

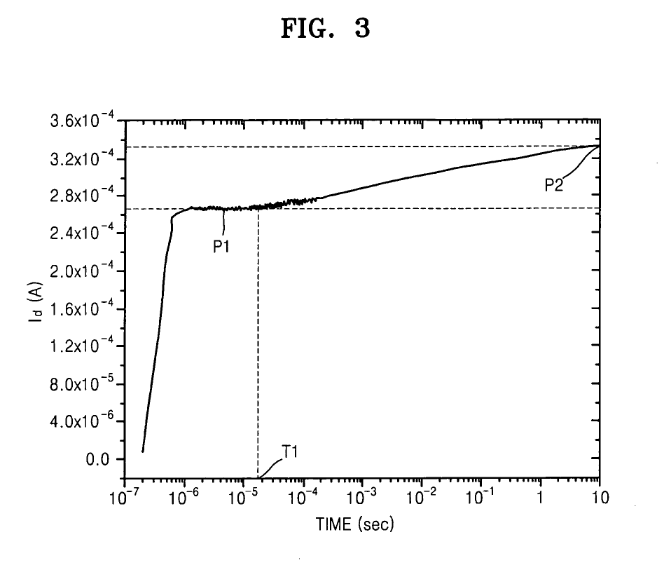

FIG. 3 is a graph showing the increase in the drain current (Id). In FIG. 3, a horizontal axis represents time (sec), and a vertical axis represents the drain current (Id). A voltage of about 4.5V may be applied to the gate electrode 60 at time (T1) in FIG. 3. As a result, the drain current (Id) may be gradually increasing from the time (T1).

A first point (P1) in FIG. 3 denotes the drain current (Id) when the electrons 1 are injected into the first and second charge trapping layers 20 and 40 as shown in FIG. 2A. A second point (P2) in FIG. 3 denotes the drain current (Id) when the electrons 1 of the first charge trapping layer 20 are moved to the second charge trapping layer 40 as shown in FIG. 2B. The drain current (Id) at the second point (P2) is about 0.6×10⁻⁴ (A) greater than the drain current (Id) at the first point (P1). Therefore, the threshold voltage at the second point (P2) may be about 0.62V less than the threshold voltage at the first point (P1).

Referring to FIGS. 2A and 2B, a state in which the electrons 1 are uniformly distributed in the first and second charge trapping layers 20 and 40 as shown in FIG. 2A, is denoted as a first state, and a state in which the electrons 1 are concentrated on the second charge trapping layer 40 as shown in FIG. 2B is denoted as a second state, and different drain currents (Id) are respectively shown in the first and second states. Accordingly, the first and second states may respectively correspond to data ‘1’ and data ‘0’. By applying a predetermined or given reading voltage to the transistor including the gate stack 200, the source 300a and the drain 300b to measure the drain current (Id), it is possible to distinguish whether data recorded in the gate stack 200 is ‘1’ or ‘0’.

The capacitorless DRAM according to example embodiments may include a plurality of unit cell structures as shown in FIG. 1. When a cell belonging to a first group of the unit cells is in the first state and a cell belonging to a second group of the unit cells is in the second state, a series of data may be written. Data ‘1’ written in the capacitorless DRAM according to example embodiments may be erased by various methods. As one example, by moving at least part of the electrons 1 concentrated on the second charge trapping layer 40 to the first charge trapping layer 20, data ‘1’ may be erased. For this, a predetermined or given negative voltage (−V) may be applied to the gate electrode 60 as shown in FIG. 2C.

Referring to FIG. 2C, by applying a predetermined or given negative voltage (−V) to the gate electrode 60, part of the electrons 1 concentrated on the second charge trapping layer 40 may be moved to the first charge trapping layer 20. The erasing of data ‘1’ may be the same as a transformation (data ‘1’ is transformed into data ‘0’) of data. For example, if the state of the capacitorless DRAM shown in FIG. 2B is transformed into the state of the capacitorless DRAM shown in FIG. 2A, data ‘1’ may be transformed into data ‘0’. Data ‘0’ may be transformed into data ‘1’ using the same method as that for transforming the state of the capacitorless DRAM shown in FIG. 2A into the state of the capacitorless DRAM shown in FIG. 2B.

Thus, most of the writing and the erasing of data using the capacitorless DRAM according to example embodiments may be performed by movement of charges through the interlayer insulating layer 30. The movement of the charges through the interlayer insulating layer 30 may be performed by applying a predetermined or given voltage to the gate electrode 60, and the voltage applied to the gate electrode 60 in order to move the charges through the interlayer insulating layer 30 may be less than the voltage consumed when the transistor is ON or OFF. Therefore, the capacitorless DRAM according to example embodiments may have a relatively low power-consumption characteristic.

Also, in the methods of writing and erasing of data using the capacitorless DRAM according to example embodiments, except when charges are injected into the first and second charge trapping layers 20 and 40 for the first time, the charges may not move through the tunnel insulating layer 10. Therefore, the capacitorless DRAM according to example embodiments may prevent or reduce characteristics of the tunnel insulating layer 10 from deteriorating, thereby having improved reliability.

In addition, in the capacitorless DRAM according to example embodiments, because the interlayer insulating layer 30 is interposed between the first charge trapping layer 20 and the second charge trapping layer 40, a distribution state of the charges in the first and second charge trapping layers 20 and 40 may not be easily changed during a reading operation. The reading voltage applied to the gate electrode 60 during the reading operation may be smaller than the voltage necessary for writing and erasing of data. The interlayer insulating layer 30 may serve to prevent or reduce the charges from moving through the interlayer insulating layer 30. Therefore, the capacitorless DRAM according to example embodiments may prevent or reduce the occurrence of a read disturbance.

A method of refreshing the capacitorless DRAM according to example embodiments will now be described. As shown in FIG. 2B, the electrons 1 concentrated in the second charge trapping layer 40 may leak in time into the first charge trapping layer 20 through the interlayer insulating layer 30. To prevent or retard an undesired transformation of data by electron leakage, a refreshing operation may be performed by applying a predetermined or given positive voltage to the gate electrode 60. For example, by applying the predetermined or given positive voltage to the gate electrode 60, the electrons 1 leaked into the first charge trapping layer 20 may be moved to the second charge trapping layer 40. Because the tunnel insulating layer 10 is formed to have a thickness of more than about 4 nm, undesired leakage of the charges through the tunnel insulating layer 10 may be properly prevented or reduced.

As described above, a capacitorless DRAM according to example embodiments may use two charge trapping layers separated by an interlayer insulating layer as areas for storing data. The capacitorless DRAM according to example embodiments may mainly read or erase data by moving charges through the interlayer insulating layer, thereby having reduced power-consumption and preventing or reducing deterioration of characteristics of the tunnel insulating layer. In addition, the interlayer insulating layer may serve to prevent or retard the distribution state of the charges of the charge trapping layers from being changed during a reading operation, thereby preventing or reducing read disturbance.

While example embodiments have been particularly shown and described with reference to embodiments thereof, it should not be construed as being limited to the embodiments set forth herein. It will be obvious to those of ordinary skill in this art that, for example, the structure and the components of the gate stack 200 shown in FIG. 1 may be respectively changed and varied, and the roles of the source 300a and the drain 300b may be reversed. Therefore, the scope of example embodiments is defined not by the detailed description of example embodiments but by the appended claims.

What is claimed is:

1. A gate stack for a capacitorless DRAM comprising:
a tunnel insulating layer on a substrate;
a first charge trapping layer on the tunnel insulating layer;
an interlayer insulating layer on the first charge trapping layer;
a second charge trapping layer on the interlayer insulating layer;
a blocking insulating layer on the second charge trapping layer; and
a gate electrode on the blocking insulating layer.

2. The gate stack of claim 1, wherein a thickness of the tunnel insulating layer is in the range of about 4 nm to about 10 nm.

3. The gate stack of claim 1, wherein the first and second charge trapping layers are one of a high dielectric layer having a dielectric constant greater than that of a silicon nitride layer, a dielectric layer doped with metals, a dielectric layer in which nano-particles are embedded, an amorphous silicon nitride layer, a crystalline silicon nitride layer, and an amorphous silicon layer.

4. The gate stack of claim 1, wherein a thickness of the first charge trapping layer is in the range of about 4 nm to about 15 nm.

5. The gate stack of claim 1, wherein a thickness of the second charge trapping layer is in the range of about 4 nm to about 15 nm.

6. The gate stack of claim 1, wherein the interlayer insulating layer is a silicon oxide layer.

7. The gate stack of claim 1, wherein a thickness of the interlayer insulating layer is in the range of about 0.5 nm to about 3 nm.

8. A capacitorless DRAM comprising the gate stack according to claim 1 on the substrate, and a source and a drain respectively formed in the substrate on both sides of the gate stack.

9. A method of manufacturing a gate stack for a capacitorless DRAM comprising:
forming a tunnel insulating layer on a substrate;
forming a first charge trapping layer on the tunnel insulating layer;
forming an interlayer insulating layer on the first charge trapping layer;
forming a second charge trapping layer on the interlayer insulating layer;
forming a blocking insulating layer on the second charge trapping layer; and
forming a gate electrode on the blocking insulating layer.

10. The method of claim 9, wherein a thickness of the tunnel insulating layer is in the range of about 4 nm to about 10 nm.

11. The method of claim 9, wherein the first and second charge trapping layers are one of a high dielectric layer having a dielectric constant greater than that of a silicon nitride layer, a dielectric layer doped with metals, a dielectric layer in which nano-particles are embedded, an amorphous silicon nitride layer, a crystalline silicon nitride layer, and an amorphous silicon layer.

12. The method of claim 9, wherein a thickness of the first charge trapping layer is in the range of about 4 nm to about 15 nm.

13. The method of claim 9, wherein a thickness of the second charge trapping layer is in the range of about 4 nm to about 15 nm.

14. The method of claim 9, wherein the interlayer insulating layer is a silicon oxide layer.

15. The method of claim 9, wherein a thickness of the interlayer insulating layer is in the range of about 0.5 nm to about 3 nm.

16. A method of manufacturing a capacitorless DRAM comprising:
forming the gate stack according to the method of claim 9 on a substrate; and
forming a source and a drain respectively in the substrate on both sides of the gate stack.

17. A method of operating a capacitorless DRAM including a gate stack in which a tunnel insulating layer, a first charge trapping layer, an interlayer insulating layer, a second charge trapping layer, a blocking insulating layer and a gate electrode are sequentially formed on a substrate, and a source and a drain respectively formed in the substrate on both sides of the gate stack,
the method comprising;
applying a voltage to the gate stack.

18. The method of claim 17, wherein the voltage is a writing voltage.

19. The method of claim 17, wherein the voltage is a reading voltage, an erasing voltage or a refreshing voltage.

20. The method of claim 18, wherein the writing voltage is a voltage for trapping charges in the first and second charge trapping layers.

21. The method of claim 20, wherein the writing voltage is applied to at least one of the source, the drain and the substrate, and the gate electrode in order to trap charges in the first and second charge trapping layers.

22. The method of claim 20, wherein the writing voltage is a first writing voltage, and after applying the first writing voltage, a second writing voltage different from the first writing voltage is applied to the gate electrode.

23. The method of claim 22, wherein the second writing voltage is a voltage used for moving at least part of the charges trapped in the first charge trapping layer to the second charge trapping layer.

24. The method of claim 23, wherein all of the charges in the first charge trapping layer are moved to the second charge trapping layer by the second writing voltage.

25. The method of claim 22, wherein after applying the second writing voltage, a voltage, which is used for moving at least part of the charges trapped in the second charge trapping layer to the first charge trapping layer, is applied to the gate electrode.
